(19) United States
(12) Patent Application Publication
(10) Pub. No.: US 2024/0006353 A1
(43) Pub. Date: Jan. 4, 2024

(54) BOND PAD TOPOLOGY TO MITIGATE CRACK FORMATION

(71) Applicant: TEXAS INSTRUMENTS INCORPORATED, Dallas, TX (US)

(72) Inventors: Anton Johann BAYERSTADLER, Ebersberg (DE); Christian SCHMITT, Munich (DE); Peter BAKKER, Freising (DE)

(21) Appl. No.: 17/855,480

(22) Filed: Jun. 30, 2022

(51) Int. Cl. H01L 23/00

(52) U.S. Cl. CPC H01L 24/05; H01L 24/49; H01L 24/03; H01L 2224/05082; H01L 2224/05011; H01L 2224/05184; H01L 2224/05124; H01L 2224/05624; H01L 2224/05147; H01L 2224/05144; H01L 2224/05647; H01L 2224/05644; H01L 2224/05013; H01L 2224/05573; H01L 2224/05562; H01L 2224/05567; H01L 2224/0362; H01L 2224/48465; H01L 2224/48482; H01L 2224/48175; H01L 24/73; H01L 2224/73265; H01L 24/32; H01L 2224/32245; H01L 2224/49176; H01L 24/48

(57) ABSTRACT

In examples, a semiconductor package comprises a bond pad surface layer, a second conductive layer positioned below the bond pad surface layer, and a perforated plate positioned between and abutting the bond pad surface layer and the second conductive layer. The perforated plate has a monolithic conductive member and multiple insulation members embedded within the conductive member, the insulation members having thicknesses approximately equivalent to that of the conductive member. The package also includes a semiconductor substrate including a circuit, the semiconductor substrate positioned below the second conductive layer.

### BACKGROUND

Semiconductor chips are often housed inside semiconductor packages that protect the chips from deleterious environmental influences, such as heat, moisture, and debris. A packaged chip communicates with electronic devices outside the package via conductive terminals, such as leads, that are exposed to surfaces of the package. Within the package, the chip may be electrically coupled to the conductive terminals using any suitable technique. One such technique is the “flip-chip” technique, in which the semiconductor chip (also called a “die”) is oriented so the device side of the chip (in which circuitry is formed) is facing downward. The device side is coupled to the conductive terminals using, e.g., solder bumps. Another technique is the wirebonding technique, in which the device side of the semiconductor chip is oriented upward and is coupled to the conductive terminals using bond wires. Wirebonds are formed on bond pads, which are positioned on semiconductor dies and provide interfaces between the wirebonds and circuitry of the semiconductor dies.

### SUMMARY

In examples, a semiconductor package comprises a bond pad surface layer, a second conductive layer positioned below the bond pad surface layer, and a perforated plate positioned between and abutting the bond pad surface layer and the second conductive layer. The perforated plate has a monolithic conductive member and multiple insulation members embedded within the conductive member, the insulation members having thicknesses approximately equivalent to that of the conductive member. The package also includes a semiconductor substrate including a circuit, the semiconductor substrate positioned below the second conductive layer.

In examples, method of manufacturing a semiconductor package comprises forming a semiconductor die, including: forming a circuit in a semiconductor substrate; depositing one or more conductive layers, including a second conductive layer, and one or more insulation layers, including a top insulation layer, above the semiconductor substrate, the top insulation layer above and abutting the second conductive layer; insulation layer etching a trench in the top insulation layer to form multiple insulation members; depositing a conductive material in the trench to form a conductive member, the multiple insulation members embedded within the conductive member; and depositing a first conductive layer above and abutting the conductive member and the multiple insulation members; bonding a bond wire to a top surface of the first conductive layer; and covering the semiconductor die and the bond wire with a mold compound.

### BRIEF DESCRIPTION OF THE DRAWINGS

FIG. 1 is a block diagram of an electronic device comprising a semiconductor package, in accordance with various examples.

FIGS. 2A-2C are profile, top-down, and perspective views of an exterior of a semiconductor package, in accordance with various examples.

FIGS. 3A-3C are profile cross-sectional, top-down, and perspective views of contents of a semiconductor package, in accordance with various examples.

FIGS. 4 and 5 are profile cross-sectional views of bond pads, in accordance with various examples.

FIGS. 6A-6E are profile cross-sectional, top-down, and perspective views of perforated plates, in accordance with various examples.

FIG. 7 is a flow diagram of a method for manufacturing a semiconductor package in accordance with various examples.

FIGS. 8A-8G are a process flow diagram for manufacturing a semiconductor package in accordance with various examples.

### DETAILED DESCRIPTION

Bond pads are electrically conductive surfaces that interface between two or more components in a semiconductor package. For example, a semiconductor package may contain a semiconductor die, and various circuitry may be formed in and/or on a device side of the semiconductor die. To facilitate the exchange of power and/or electrical signals between the circuitry and components outside the circuitry, such as a semiconductor package lead, a bond wire may be coupled between the circuitry and the component outside the circuitry (e.g., a lead). However, the bond wire generally cannot be coupled directly to the circuit. Instead, a bond pad is formed on the device side of the semiconductor die, and the bond pad is coupled to the circuitry. Thus, bonding a bond wire to the bond pad forms an electrical pathway between the bond wire and the circuitry of the semiconductor die to which the bond pad is coupled. A distal end of the bond wire may be coupled to, e.g., a lead of the semiconductor package, and other electrical components may be coupled to that lead. In this way, an electrical pathway is established between various electrical components by way of the bond pad.

Some types of bond pads are formed directly over (e.g., in vertical alignment with) circuitry of the semiconductor die. These bond pads may be referred to as bonds over active circuit bond pads, or BOAC bond pads. BOAC bond pads and other, similar bond pads are advantageous because they conserve space within the semiconductor package by being positioned above, rather than around the perimeter of, semiconductor die circuitry.

One drawback to such bond pads is the formation of cracks within the bond pad topology inside the bond pad window, which is the space below the area of the bond pad surface on which bonds are formed and probe needles are applied. Specifically, when a force is applied to the bond pad, such as during wirebonding or needle probing, the weak metal (e.g., aluminum) of which the bond pad surface is composed transfers the force to the components underlying the bond pad surface, such as inter-layer oxides (ILOs), conductive layers, and semiconductor layers (e.g., silicon) with active and/or passive components formed within the semiconductor layers. The transfer of this force into the layers underneath the bond pad surface, particularly because it is concentrated in a limited area, frequently introduces cracks in such layers. These cracks, in turn, can cause leakage or short circuits between adjacent electrically conductive components or layers. Such mechanical damage can also result in the shifting of the electrical properties of the components under the bond pad surface. Such mechanical damage can compromise the structural and/or functional integrity of conductive layers, ILOs, semiconductor layers, and active and/or passive components formed in the semiconductor layers.

This disclosure describes various examples of a bond pad that includes a perforated plate positioned below and abutting the bond pad surface. The term “bond pad,” as used herein, refers to the conductive layer accessible at the surface to wirebonding capillaries and other equipment, as well as other structures (e.g., the perforated plate, additional conductive layers, insulation layers, vias, etc.) below such a surface-level conductive layer. The perforated plate may have a honeycomb structure in a top-down view in some examples. The perforated plate may include a monolithic conductive member having multiple insulation layers embedded within the monolithic conductive member, as described in more detail below. The perforated plate receives a force applied to the bond pad surface (e.g., during wirebonding, during needle probing) and distributes the force across a relatively large horizontal area of the structure(s) below the perforated plate. For example, if a perforated plate is positioned between and abutting a first conductive layer (e.g., the bond pad surface) and a second conductive layer, the perforated plate distributes the force applied to the first conductive layer across a relatively large horizontal area of the second conductive layer. The distributed forces applied to the second conductive layer are also then transferred to other layers below the second conductive layer in a distributed manner. In this way, the force applied to the first conductive layer (e.g., the bond pad surface) is not concentrated in a singular area (e.g., the small wired or ball bonded area on the bond pad surface), thereby mitigating the risk of crack formation and the resulting problems typically associated with crack formation, such as vertical parasitic leakage paths between different conductive layers along a crack in an insulation layer (referred to as an IL, such as an oxide layer) or horizontal leakage paths between deformed metal lines of the same conductive layer.

The addition of perforated plates provides numerous advantages to bond pads, and particularly to BOAC bond pads. For example, crack mitigation provided by perforated plates enables conductive layers to be positioned in the bond window. Without the perforated plate, conductive layers in the bond window are highly susceptible to the mechanical problems described above. Furthermore, the perforated plate provides electrical pathways for both electrical signals and power to be transferred between the bond pad surface and components (e.g., conductive layers, circuitry) below the bond pad surface, as opposed to traditional bond pad topologies (e.g., BOAC) that are often limited to a few vias along the bond pad periphery and, therefore, limited to non-power electrical signals. Further still, the frequent touching of a needle probe on the bond pad surface may erode the bond pad surface, thereby exposing the underlying structure. If a perforated plate is present below the bond pad surface, an electrical connection is still possible to the perforated plate, because the perforated plate is a conductive metal. Thus, wirebonds may still be formed on an eroded bond pad surface, even if such wirebonds are partially coupled to the bond pad surface and partially coupled to the underlying perforated plate. Yet further still, the stiffness of the perforated plate, which is a parameter that influences crack formation, may be tuned by adjusting the size of the perforated plate and the pitch of oxide members in the perforated plate as described below. The IL material and properties, which would traditionally be adjusted in an effort to mitigate crack formation and would present the risk of shifting electrical properties of the bond pad and circuitry coupled to the bond pad, need not be adjusted in a bond pad having a perforated plate. In addition, in traditional bond pads, further pressure may be applied to a probe needle failing to establish adequate contact with the bond pad surface, in an effort to improve the needle contact. Such pressure would increase crack formation risk in traditional bond pads. In bond pads having perforated plates, however, such additional pressure is distributed over a large area as described above, thereby mitigating the risk of crack formation. Finally, bond pads having perforated plates mitigate the risk of bond pad surface lifting, as the perforated plate anchors the bond pad surface layer (which is the top conductive layer in the bond pad and, in at least some examples, is not a composite layer) to the next conductive layer below the bond pad surface layer. These and other advantages make bond pads having perforated plates a superior option over traditional bond pads.

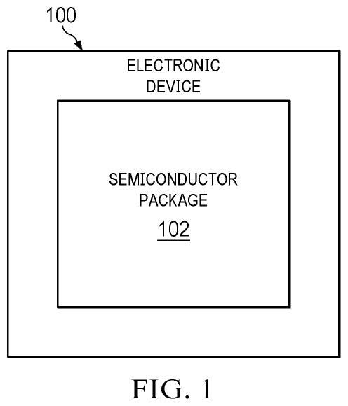

FIG. 1 is a block diagram of an electronic device 100 comprising a semiconductor package, in accordance with various examples. The electronic device 100 may include, for example, an automobile, aircraft, spacecraft, appliance, smartphone, personal electronic device, entertainment device or system, etc. The electronic device 100 includes a semiconductor package 102. For example, the semiconductor package 102 may be coupled to a printed circuit board (PCB) included in the electronic device 100. The semiconductor package 102 includes one or more perforated plates (e.g., one perforated plate for each bond pad), as described below.

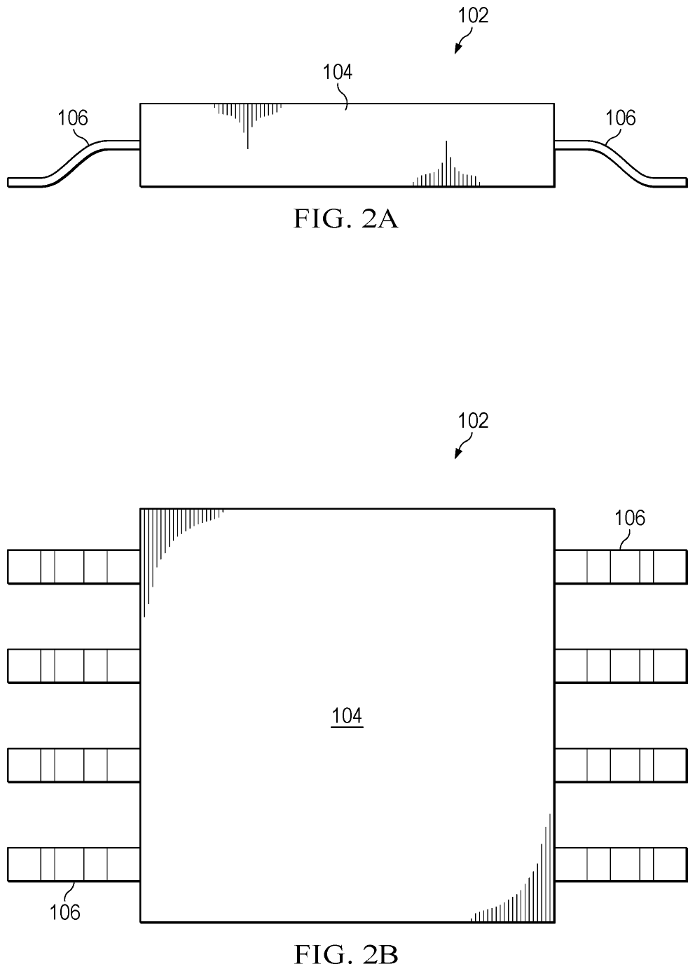

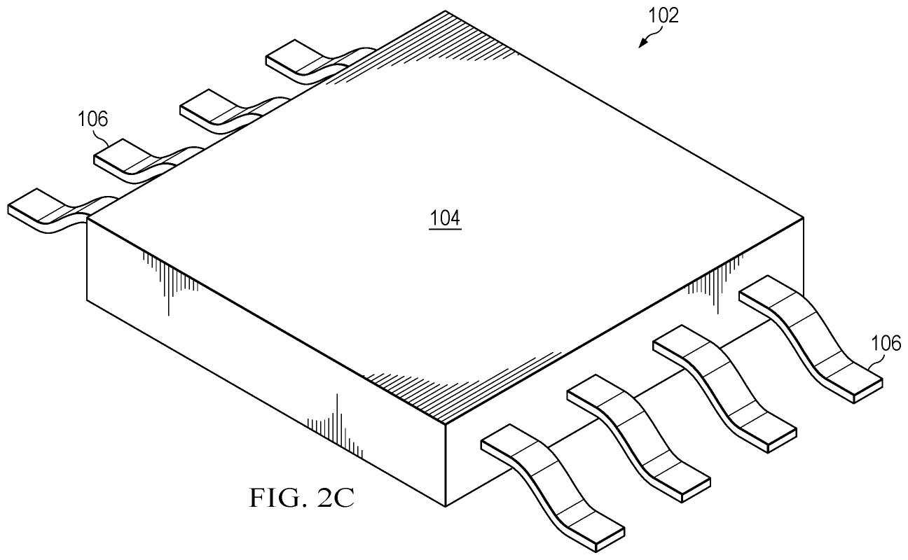

FIGS. 2A-2C are profile, top-down, and perspective views of an exterior of the semiconductor package 102, in accordance with various examples. The semiconductor package 102 may be any suitable type of package that includes wire bonds within, including single inline packages (SIP), dual inline packages (DIP), quad flat no lead packages (QFN), ball grid array packages (BGA), etc. The semiconductor package 102 may include a mold compound 104 that covers a semiconductor die, bond wires, and other components as described below. Conductive terminals 106 extend from within the mold compound 104 to an exterior of the semiconductor package 102, thereby facilitating communications between a semiconductor die in the semiconductor package 102 and one or more electrical components exterior to the semiconductor package 102 (e.g., electrical components coupled to the same PCB as the semiconductor package 102).

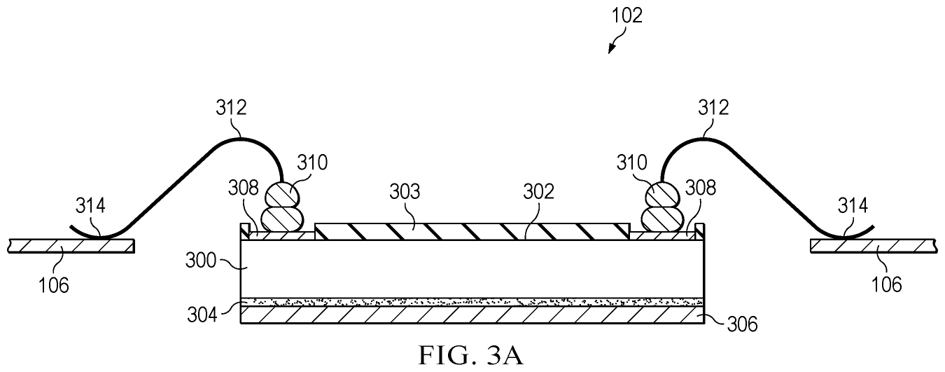

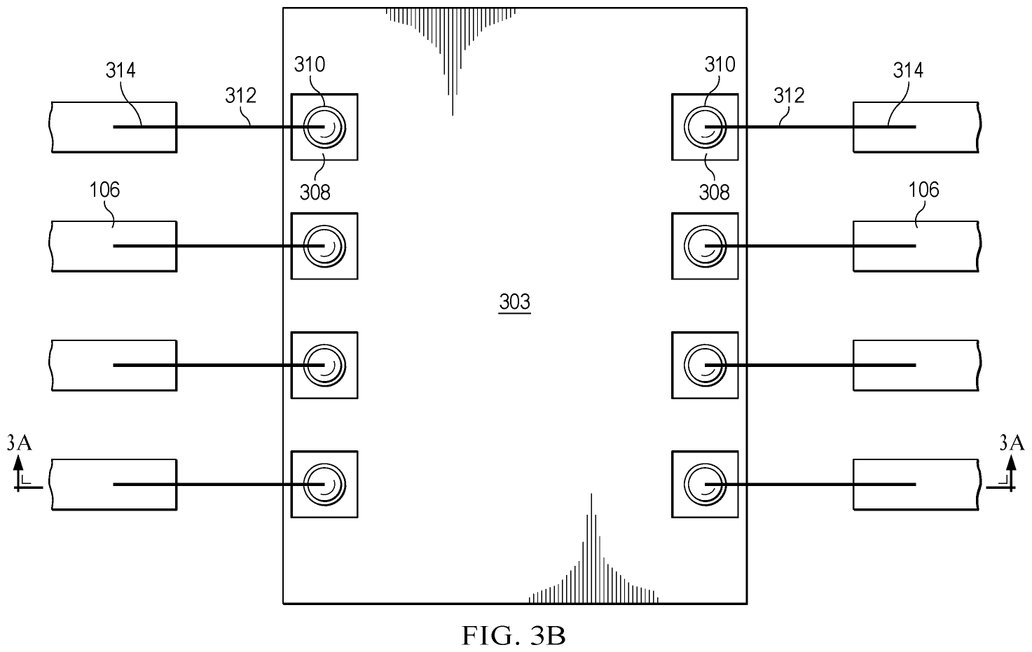

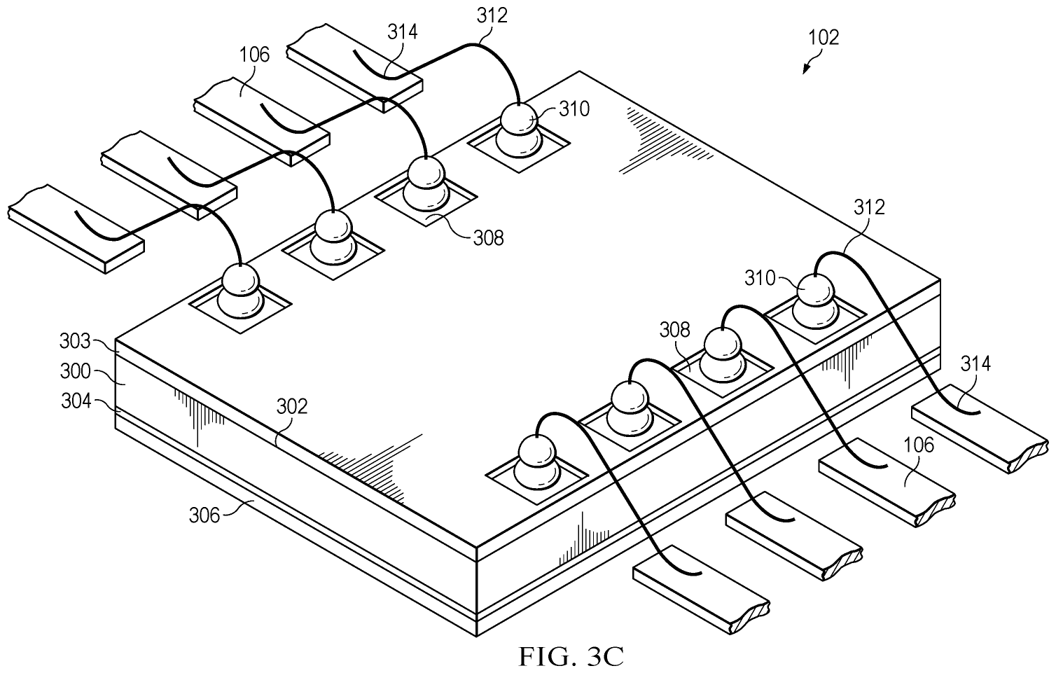

FIGS. 3A-3C are profile cross-sectional, top-down, and perspective views of contents of the semiconductor package 102, in accordance with various examples. The semiconductor package 102 includes a semiconductor die 300 coupled to a die pad 306 by way of a die attach layer 304. The semiconductor die 300 has a device side 302 in and/or on which one or more circuits and/or metallization layers are formed. The device side 302 also includes bond pads 308. Ball bonds 310 are coupled to the bond pads 308, and the ball bonds 310 are contiguous with bond wires 312. The bond wires 312, in turn, bond to conductive terminals 106 by way of bonds 314 (e.g., stitch bonds). In this way, an electrical pathway is established between the circuitry of the semiconductor die 300 and electrical components exterior to the semiconductor package 102. The bond pads 308 include perforated plates, as described below. A passivation layer 303 abuts and covers areas of the semiconductor die 300 other than the bond windows of the bond pads 308. FIG. 3B is a top-down view of the structure of FIG. 3A. FIG. 3C is a perspective view of the structure of FIG. 3A.

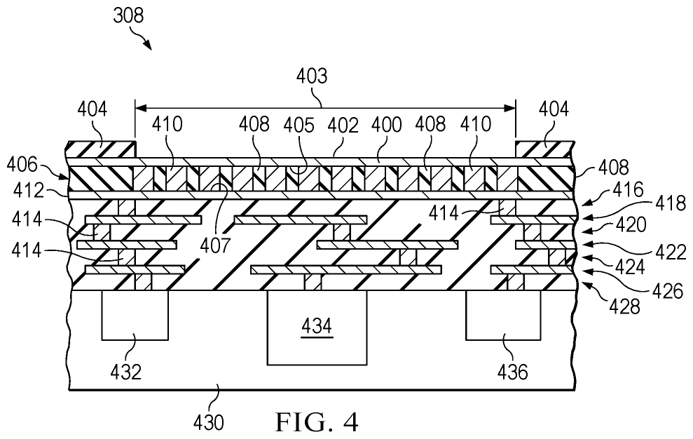

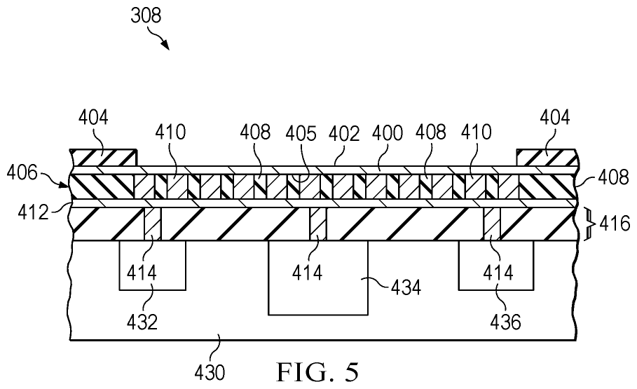

FIGS. 4 and 5 are profile cross-sectional views of bond pads 308, in accordance with various examples. The bond pads 308 may, for instance, be the bond pads 308 included in the example semiconductor package 102 of FIGS. 1-3C. A portion of the bond pad 308 may be positioned on or above the device side 302 of the semiconductor die 300 (FIG. 3A). Other portions of the bond pad 308 may be positioned within the semiconductor die 300 (FIG. 3A). An example bond pad 308 may include a bond pad surface layer 400. In examples, the bond pad surface layer 400 is a conductive layer (and may be referred to as a first conductive layer 400) composed of a suitable metal, such as aluminum. Other example metals suitable for inclusion in the bond pad surface layer 400 include copper and gold. Still other metals or metal alloys may be included. The bond pad surface layer 400 has a thickness ranging from 700 nm to 3 microns, with a thickness above this range being disadvantageous because it occupies excessive space within the semiconductor package, and with a thickness below this range being disadvantageous because it readily permits damage to the bond pad surface layer and/or underlying structures. The bond pad surface layer 400 includes a surface 402 on which wirebonds may be formed. For example, bond wires may be bonded to the surface 402 using ball bonds, stitch bonds, or any other suitable type of bond. A passivation layer 404 (e.g., silicon nitride) may circumscribe the surface 402, for example, along a perimeter of the surface 402, to protect the die area outside the bond window from corrosion, moisture, mechanical damage, etc. The exposed portion of the surface 402 (i.e., the portion of the surface 402 not covered by the passivation layer 404) defines a bond window 403 within which wirebonds may be formed. Structures of the bond pad 308 below the surface 402 that are in vertical alignment with the bond window of the surface 402 are also said to be within the bond window.

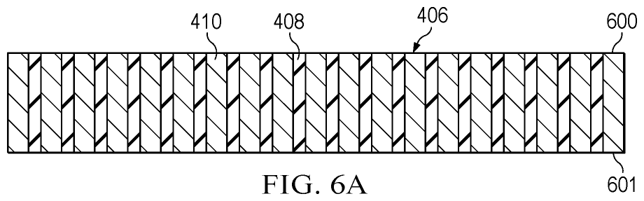

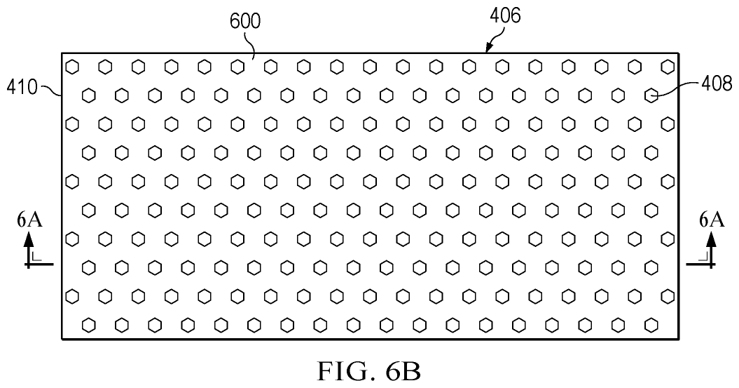

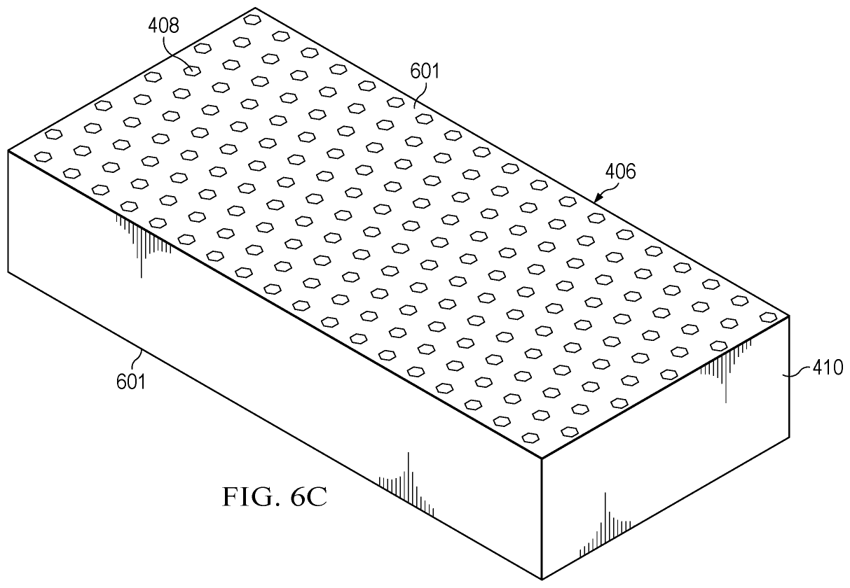

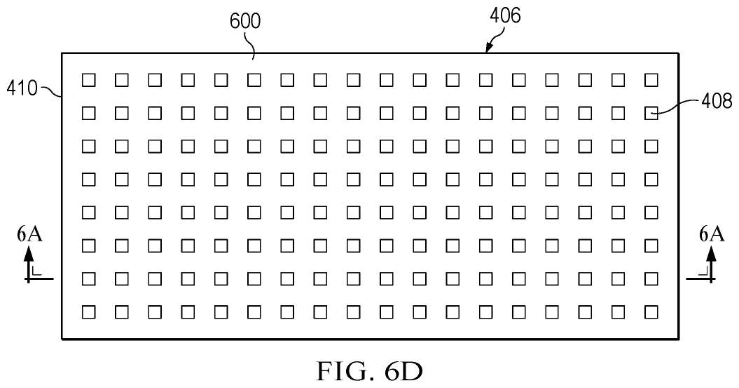

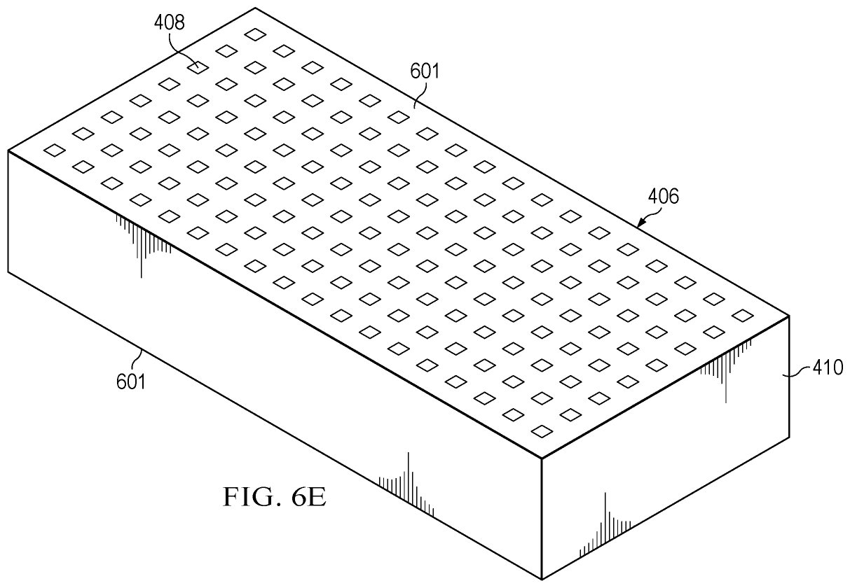

The example bond pad 308 includes a perforated plate 406. The perforated plate 406, described in greater detail below, includes a monolithic and relatively stiff conductive (e.g., metal or alloy) structure that abuts a bottom surface 405 of the bond pad surface layer 400 and abuts a top surface 407 of a second conductive layer 412. Specifically, the perforated plate 406 includes a conductive member 410 and insulation members 408 (e.g., oxides, nitride, or oxynitrides). As described in greater detail with reference to FIGS. 6A-6E, the conductive member 410 is a monolithic structure and includes vertical insulation members 408 distributed throughout the conductive member 410. In examples, the conductive member 410 and the insulation members 408 have the same or approximately the same thickness. In examples, the conductive member 410 is composed of a different metal or alloy (e.g., tungsten) than the first and second conductive layers 400, 412 (e.g., aluminum, copper, gold). In examples, the insulation members 408 of the perforated plate 406 abut the surfaces 405, 407. In examples, the passivation layer 404 clamps the perforated plate 406 and the first and second conductive layers 400, 412 in place, such that when a downward force is applied to the first conductive layer 400, the resultant bowing of one or more of the first and second conductive layers 400, 412 and the perforated plate 406 (e.g., downward in the middle of these layers and upward on the opposing ends of these layers) is mitigated. In examples, the horizontal area of the perforated plate 406 is at least as large as that of the bond window 403.

The bond pad 308 includes several conductive layers and insulation layers (ILs, e.g., oxides, nitrides, or oxynitrides) positioned below the second conductive layer 412. For example, the bond pad 308 includes an IL 416 abutting the second conductive layer 412. The bond pad 308 includes a conductive layer 418 abutting the IL 416. The bond pad 308 includes an IL 420 abutting the conductive layer 418. The bond pad 308 includes a conductive layer 422 abutting the IL 420. The bond pad 308 includes an IL 424 abutting the conductive layer 422. The bond pad 308 includes a conductive layer 426 abutting the IL 424. The bond pad 308 includes an IL 428 abutting the conductive layer 426. Each of the conductive layers 418, 422, and 426 may be formed in any suitable pattern to achieve desired circuit connections between circuits 432, 434, and/or 436 in a semiconductor substrate 430 abutting the IL 428. Similarly, various segments of each of the conductive layers 418, 422, and/or 426 may be coupled to each other and/or to circuits 432, 434, and/or 436 by way of vias (or plugs) 414. The conductive layers 418, 422, and/or 426 may be composed of the same or similar material as the conductive layers 400, 412. The ILs 416, 420, 424, and/or 428 may be composed of the same or similar material as the insulation members 408. The conductive layers 418, 422, and/or 426 and the ILs 416, 420, and/or 424 may have any suitable size, shape, stiffness, or other physical properties. The circuits 432, 434, and/or 436 may in some examples be components or portions of circuits. In examples, the circuits 432, 434, and/or 436 are passive and/or active circuit components. In examples, the semiconductor substrate 430 is a silicon substrate, although the scope of this disclosure is not limited to any particular semiconductor material. The bond pad 308 does not include the semiconductor substrate 430 or the structures in the substrate 430.

FIG. 4 shows specific numbers of metal and IL layers (e.g., conductive layers 418, 422, 426; ILs 416, 420, 424, 428). The scope of this disclosure, however, is not limited to the application of the perforated plate in bond pad topologies having any specific or particular number of metal and/or IL layers.

In traditional bond pad topologies (e.g., BOAC), the second conductive layer 412 could not be safely positioned within the bond window 403 as it is in bond pad 308, because force applied on surface 402 would transfer to the insulation layer that would be present between the conductive layers 400, 412 in lieu of the perforated plate 406, and this force would introduce cracks into the insulation layer. Such cracks could cause leaking and/or short circuits, for example, by facilitating contact between the conductive layers 400, 412 through such cracks in the insulation layer. In some cases, a via would be positioned in the insulation layer between the conductive layers 400, 412, and the force applied to the surface 402 would be concentrated in that via, thereby facilitating the formation of cracks. The force applied to the surface 402 could damage areas beyond the insulation layer between the conductive layers 400, 412, including some or all IL and/or conductive layers below the conductive layer 412, and including the semiconductor substrate 430 and some or all structures (e.g., circuits or circuit components) within the semiconductor substrate 430.

However, the introduction of the perforated plate 406 in between the conductive layers 400, 412 and in lieu of the insulation layer that would traditionally be positioned between the conductive layers 400, 412 provides several advantages. For example, crack mitigation provided by the perforated plate 406 enables second conductive layer 412 to be positioned in the bond window 403. Without the perforated plate 406, conductive layers in the bond window 403 are highly susceptible to the mechanical problems described above. Furthermore, perforated plate 406 provides electrical pathways for both electrical signals and power to be transferred between the bond pad surface layer 400 and components (e.g., conductive layers, circuitry) below the bond pad surface layer 400, as opposed to traditional bond pad topologies that are often limited to a few vias along the bond pad periphery and, therefore, limited to non-power electrical signals. Further still, the frequent touching of a needle probe on the bond pad surface layer 400 may erode the bond pad surface layer 400, thereby exposing the underlying structure. If the perforated plate 406 is present below the bond pad surface layer 400, an electrical connection is still possible to the perforated plate 406, because the perforated plate 406 is a conductive metal. Thus, wirebonds may still be formed on an eroded bond pad surface layer 400, even if such wirebonds are partially coupled to the bond pad surface layer 400 and partially coupled to the underlying perforated plate 406. Yet further still, the stiffness of the perforated plate 406, which is a parameter that influences crack formation, may be tuned by adjusting the width of the perforated plate 406 and the pitch of the insulation members in the perforated plate 406 as described herein. The IL material and properties, which would traditionally be adjusted in an effort to mitigate crack formation and would present the risk of shifting electrical properties of the bond pad, need not be adjusted in a bond pad 308 having a perforated plate 406. In addition, in traditional bond pads, further pressure may be applied to a probe needle failing to establish adequate contact with the bond pad surface, in an effort to improve the needle contact. Such pressure would increase crack formation risk in traditional bond pads. In bond pads 308 having perforated plates 406, such additional pressure is distributed over a large area (e.g., the bond window 403) as described above, thereby mitigating the risk of crack formation. Finally, bond pads 308 having perforated plates 406 mitigate the risk of bond pad surface layer 400 lifting, as the perforated plate 406 anchors the bond pad surface layer 400 to the second conductive layer 412. These and other advantages make bond pads 308 having perforated plates 406 a superior option over traditional bond pads.

In some examples, the conductive layers 418, 422, and/or 426 and/or the ILs 416, 420, 424, and/or 428 may be omitted, and the semiconductor substrate 430 may be coupled to and directly abut the conductive layer 412 such that appropriate electrical pathways are formed. In other examples, such as in FIG. 5, the conductive layers 418, 422, and 426 and the ILs 420, 424, and 428 may be omitted. In such examples, the IL 416 remains between the second conductive layer 412 and the semiconductor substrate 430, and vias 414 are coupled to the circuits 432, 434, 436 and the second conductive layer 412 such that appropriate electrical pathways are formed. Example perforated plates 406 are now described in greater detail with reference to FIGS. 6A-6E.

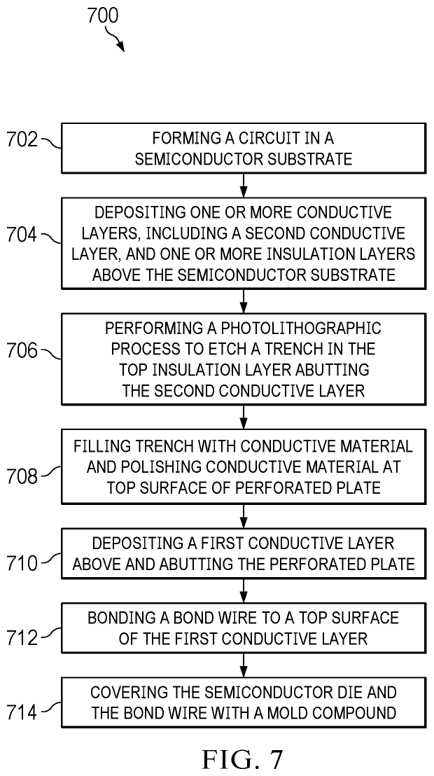

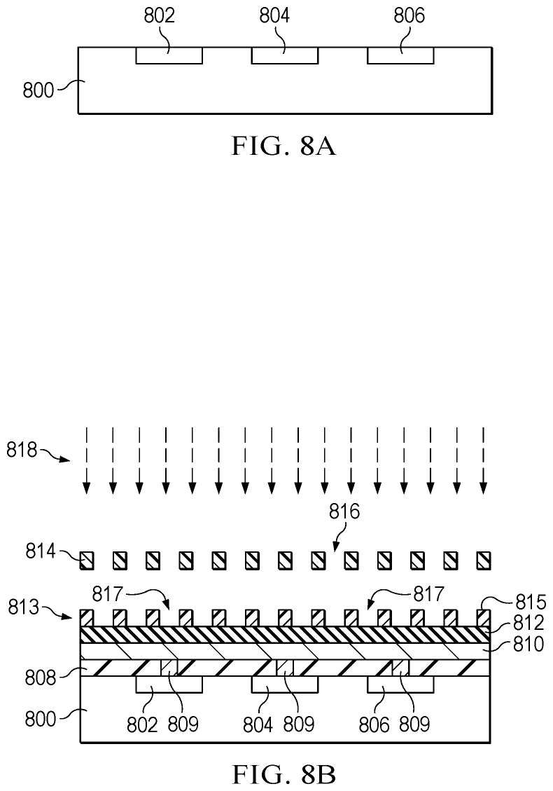

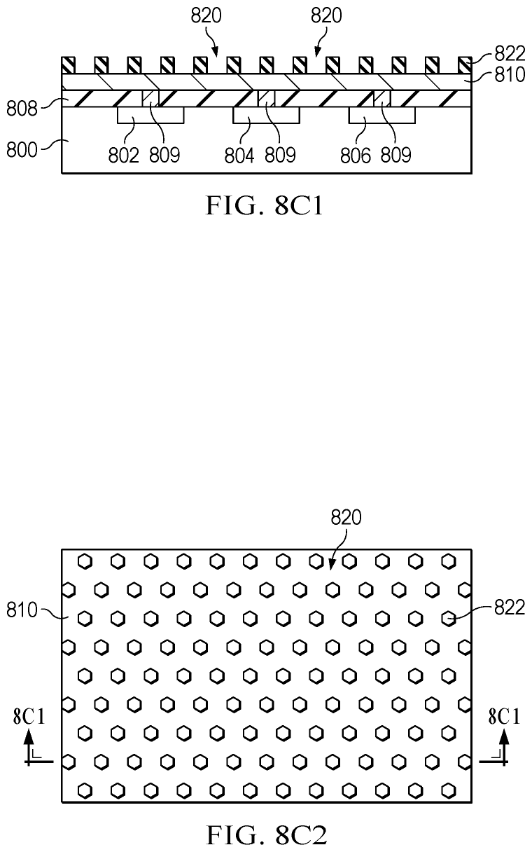

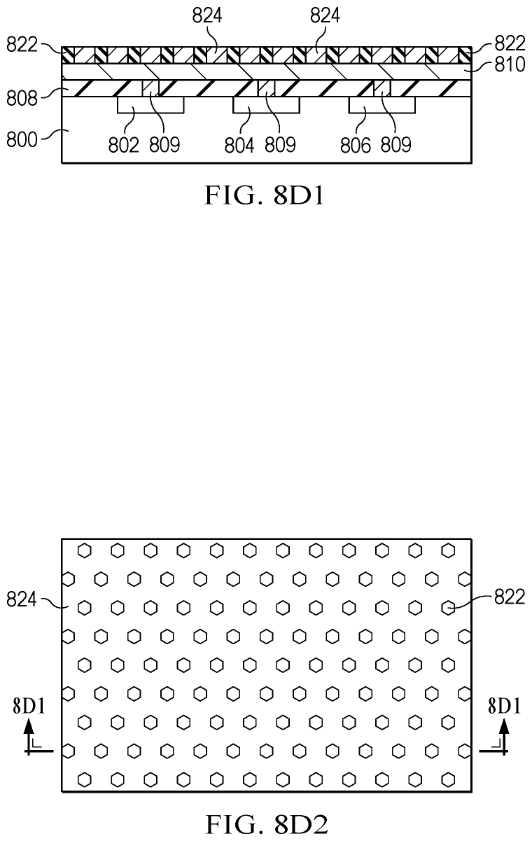

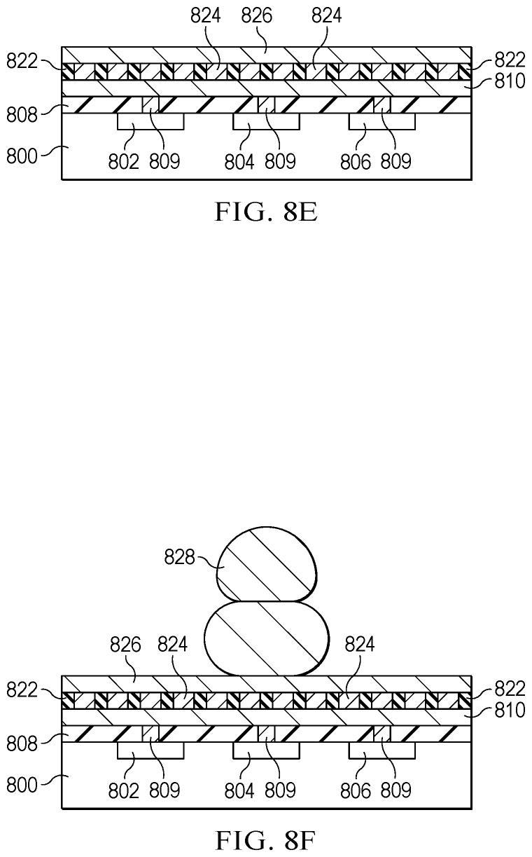

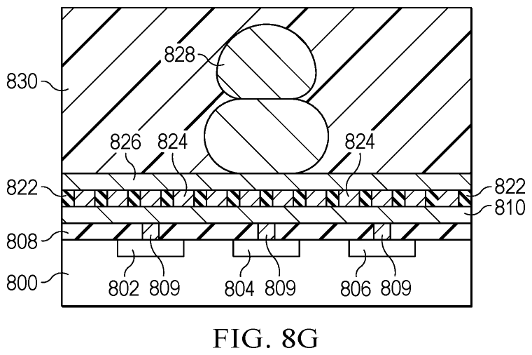

FIGS. 6A-6E are profile cross-sectional, top-down, and perspective views of a perforated plate 406, in accordance with various examples. As described above, the perforated plate 406 includes a plurality of insulation members 408 and a conductive member 410 between a top surface 600 and a bottom surface 601. Although there appear to be multiple conductive members 410, this is due to the cross-sectional nature of the view in FIG. 6A, and in fact the conductive member 410 is a monolithic structure, as is more readily apparent in FIGS. 6B and 6C. The insulation members 408 and the conductive member 410 extend through a thickness of the perforated plate 406 and have approximately the same thickness. The pitch between the insulation members 408, the size of the perforated plate 406, or a combination thereof may be adjusted as necessary to achieve a necessary stiffness of the perforated plate 406 in a given application to avoid crack formation as described herein. The conductive member 410 is composed of tungsten or another metal or metal alloy. As described below with reference to FIG. 7 and FIGS. 8A-8G, the perforated plate 406 is formed by depositing an insulation layer on a conductive layer of the bond pad, performing a photolithographic process on the insulation layer to form a trench (e.g., in a honeycomb pattern), and depositing a suitable metal or alloy (e.g., tungsten) in the trench to form the monolithic conductive member 410. Although the conductive member 410 is monolithic, the insulation layer is segmented into individual insulation members 408. In examples, the insulation members 408 may be regularly or irregularly spaced from each other. In examples, the insulation members 408 may have a horizontal cross-sectional shape of a hexagon, octagon, circle, square, or any other suitable shape. As shown in FIG. 6B, in a top-down view, the conductive member 410 may have a honeycomb pattern. Other patterns for the conductive member 410 are contemplated, such as a grid or hashtag pattern shown in FIGS. 6D and 6E, in which the conductive members may be regularly or irregularly spaced. These patterns may be formed using techniques similar to those described herein for the structures shown in FIGS. 6A-6C. A grid or hashtag pattern (e.g., in FIGS. 6D and 6E) is one in which the conductive member includes a first set of vertical segments in parallel with each other and a second set of vertical segments in parallel with each other, where the vertical segments in the first set are orthogonal to the vertical segments in the second set. Such a grid, in a top-down view, could include a regular or irregular lattice of squares, rectangles, parallelograms, etc. In some examples, a grid pattern may have vertical segments which, in the top-down view, are not consistently parallel or orthogonal with each other, such as a triangular or polygonal grid pattern.

FIG. 7 is a flow diagram of a method 700 for manufacturing a semiconductor package, such as the semiconductor package 102, in accordance with various examples. FIGS. 8A-8G are a process flow for manufacturing a semiconductor package, such as the semiconductor package 102, in accordance with various examples. Accordingly, FIGS. 7 and 8A-8G are described in parallel. The method 700 may include forming a circuit in a semiconductor substrate (702) and depositing one or more conductive layers, including a second conductive layer, and one or more insulation layers above the semiconductor substrate (704). The method 700 includes performing a photolithographic process to etch a trench in the top insulation layer abutting the second conductive layer (706). FIG. 8A shows a semiconductor substrate 800 in which example circuits 802, 804 and 806 are formed. FIG. 8B shows an insulation layer (e.g., IL) 808 abutting the semiconductor substrate 800, a conductive layer 810 abutting the IL 808, and an IL 812 abutting the conductive layer 810. A photoresist 813 abuts the IL 812. FIG. 8B also shows a patterned mask 814 having orifices 816 formed therein. Light 818 is applied through the mask 814 to expose the photoresist 813 and the photoresist 813 is subsequently developed, forming the shown pattern in the photoresist 813, including trench 817 and isles 815 between the trench 817, shown in FIG. 8B. As FIG. 8C1 shows, an etching process produces a trench 820 in the IL 812. Although the view of FIG. 8C1 suggests there are multiple trenches 820, in examples, a single trench 820 is formed, and this trench 820 separates the insulation members 822 from each other. This is more readily apparent in the top-down view of FIG. 8C2.

It is critical that the photoresist 813 be exposed and developed correctly to form the trench 820 in the IL 812. Specifically, if the trench 817 is formed such that the isles 815 have widths that are too small, the insulation members 822 will not be properly formed, and in lieu of the insulation members 822 there may be an irregularly shaped portion of the IL 812. When the conductive material (e.g., metal or alloy) is subsequently deposited into the IL 812, instead of forming a conductive member 824 as shown in FIG. 8D1 having a thickness similar to or the same as that of the insulation members 822, the conductive material instead forms a thin layer in the irregularly shaped portion of the IL 812. Consequently, a perforated plate such as that shown in FIG. 8D1 fails to materialize. Conversely, if the isles 815 are too wide, there may be an insufficient amount of conductive material in the conductive member 824, thereby reducing electrical connectivity between the first and second conductive layers on either side of the perforated plate, and also reducing stiffness of the perforated plate, thereby reducing the plate's ability to properly distribute applied forces as described above. If a cross-sectional segment of the trench 817 is not adequately wide, the corresponding cross-sectional segment of the trench 820 formed in the IL 812 will be inappropriately narrow, and thus deposition of a conductive material (e.g., tungsten) in the trench 820 becomes difficult, with the trench 820 being only partially filled or not containing any conductive material at all. Conversely, if a cross-sectional segment of the trench 817 is too wide, the corresponding cross-sectional segment of the trench 820 formed in the IL 812 will also be too wide, and thus any conductive material deposited in the trench 820 will coat only the walls of the trench 820, thereby failing to form a conductive member 824 as shown in FIG. 8D1. Thus, it is critical that the isles 815 and trenches 817 have appropriate dimensions, which can be determined by an engineer or designer based on the specific technology being used to form the structures shown in the process flow of FIGS. 8A-8G. The appropriate dimensions are those necessary to form the specific structures, and particularly the perforated plate, described herein. In this way, a relatively thin conductive layer process (e.g., 200 nm tungsten) can be used to completely fill a trench 820 in an IL 812 that is substantially thicker than the conductive layer process (e.g., 3 microns), assuming that the trench 820 is sized appropriately, as described above.

The method 700 includes filling the trench with a suitable conductive material and polishing the metal or alloy at a top surface of the perforated plate (708). FIG. 8D1 shows the trench 820 filled with a suitable conductive material (e.g., tungsten) to form a monolithic conductive member 824. FIG. 8D2 is a top-down view of the structure of FIG. 8D1. The method 700 includes depositing a first conductive layer above and abutting the perforated plate (710). FIG. 8E shows the structure of FIG. 8D1, but with the addition of a first conductive layer 826 above and abutting the insulation members 822 and conductive member 824. The method 700 includes bonding a bond wire to a top surface of the first conductive layer (712). FIG. 8F shows the structure of FIG. 8E, but with the addition of a ball bond 828 on the first conductive layer 826. The method 700 includes covering the semiconductor die and the bond wire with a mold compound (714). FIG. 8G shows the structure of FIG. 8F, but with the addition of a mold compound 830.

Unless otherwise stated, “about,” “approximately,” or “substantially” preceding a parameter means being within +/−10 percent of that parameter. Modifications are possible in the described examples, and other examples are possible within the scope of the claims.

What is claimed is:

1. A semiconductor package, comprising:
a bond pad surface layer;
a second conductive layer positioned below the bond pad surface layer;
a perforated plate positioned between and abutting the bond pad surface layer and the second conductive layer, the perforated plate having a monolithic conductive member and multiple insulation members embedded within the conductive member, the insulation members having thicknesses approximately equivalent to that of the conductive member; and
a semiconductor substrate including a circuit, the semiconductor substrate positioned below the second conductive layer.

2. The semiconductor package of claim 1, wherein the conductive member includes a first vertical segment and a second vertical segment, and wherein the first and second vertical segments are orthogonal to each other in a top-down view.

3. The semiconductor package of claim 1, wherein the multiple insulation members are composed of an oxide, a nitride, or an oxynitride.

4. The semiconductor package of claim 1, wherein the semiconductor substrate abuts the second conductive layer.

5. The semiconductor package of claim 1, wherein the perforated plate has a honeycomb structure or a grid structure in a top-down view.

6. The semiconductor package of claim 1, further comprising a passivation layer on a top surface of the bond pad surface layer, the passivation layer having a gap defining a bond window of the bond pad surface layer, the second conductive layer having a segment vertically coincident with the bond window of the bond pad surface layer.

7. The semiconductor package of claim 1, wherein the conductive member is composed of tungsten.

8. The semiconductor package of claim 1, wherein the perforated plate has a horizontal area at least as large as a horizontal area of a bond window defined by a passivation layer abutting the bond pad surface layer.

9. A semiconductor package, comprising:
a first conductive layer;
a second conductive layer positioned below the first conductive layer;
a perforated plate positioned between and abutting the first and second conductive layers, the perforated plate having a conductive member configured to distribute a force applied to the first conductive layer across an area of the second conductive layer, the conductive member having insulation members embedded therein;
one or more conductive layers positioned below the second conductive layer and separated from each other by insulation layers; and
a semiconductor substrate including a circuit, the semiconductor substrate positioned below the one or more conductive layers.

10. The semiconductor package of claim 9, further comprising a wirebond on a top surface of the first conductive layer, and wherein the insulation layers lack a crack caused by the formation of the wirebond on the top surface of the first conductive layer.

11. The semiconductor package of claim 9, wherein the semiconductor substrate abuts one of the one or more conductive layers.

12. The semiconductor package of claim 9, wherein the perforated plate has a honeycomb structure in a top-down view.

13. The semiconductor package of claim 9, further comprising a passivation layer on a top surface of the first conductive layer, the passivation layer having a gap defining a bond window of the first conductive layer, the second conductive layer having a segment vertically coincident with the bond window of the first conductive layer.

14. The semiconductor package of claim 9, wherein the perforated plate is composed of tungsten.

15. The semiconductor package of claim 9, wherein the perforated plate has a horizontal area at least as large as a horizontal area of a bond window defined by a passivation layer abutting the first conductive layer.

16. A method of manufacturing a semiconductor package, comprising:
forming a semiconductor die, including:
forming a circuit in a semiconductor substrate;
depositing one or more conductive layers, including a second conductive layer, and one or more insulation layers, including a top insulation layer, above the semiconductor substrate, the top insulation layer above and abutting the second conductive layer;
insulation layer etching a trench in the top insulation layer to form multiple insulation members;
depositing a conductive material in the trench to form a conductive member, the multiple insulation members embedded within the conductive member; and
depositing a first conductive layer above and abutting the conductive member and the multiple insulation members;
bonding a bond wire to a top surface of the first conductive layer; and
covering the semiconductor die and the bond wire with a mold compound.

17. The method of claim 16, wherein the bonding of the bond wire does not form a crack in the one or more insulation layers and does not form a crack in the multiple insulation members.

18. The method of claim 16, wherein the conductive member is composed of tungsten.

19. The method of claim 16, wherein, in a top-down view, the conductive member has a grid pattern.

20. The method of claim 16, wherein, in a top-down view, the conductive member has a honeycomb structure.

21. The method of claim 16, wherein the bond wire is bonded to the first conductive layer and to a portion of the conductive member through an orifice in the first conductive layer.
